(19) United States
(12) Patent Application Publication
(10) Pub. No.: US 2026/0344544 A1
(43) Pub. Date: Oct. 29, 2026

(54) SEMICONDUCTOR DEVICE AND METHOD OF FABRICATING THE SAME

(71) Applicant: YANGTZE MEMORY TECHNOLOGIES CO., LTD., Wuhan (CN)

(72) Inventors: Libo MEI, Wuhan (CN); Xujie WANG, Wuhan (CN); Bo WEN, Wuhan (CN); Wenjun HUANG, Wuhan (CN); Qijun WANG, Wuhan (CN)

(73) Assignee: YANGTZE MEMORY TECHNOLOGIES CO., LTD., Wuhan (CN)

(21) Appl. No.: 19/411,798

(22) Filed: Dec. 8, 2025

(30) Foreign Application Priority Data
Apr. 25, 2025 (WO) PCT/CN2025/091123
Nov. 19, 2025 (CN) 202511705100.9

(51) Int. Cl. H10W 90/00; H10W 20/43; H10W 80/00; H10W 90/26

(52) U.S. Cl. CPC H10W 90/792; H10W 20/43; H10W 80/312; H10W 90/26

(57) ABSTRACT

A semiconductor device includes a first semiconductor structure and a second semiconductor structure bonded over the first semiconductor structure. The device further includes a first chain including a plurality of first bonding pad pairs, each first bonding pad pair having a first bonding pad in the first semiconductor structure and a second bonding pad in the second semiconductor structure that are bonded together. A second bonding pad pair, not belonging to the first chain and adjacent to at least one of the first bonding pad pairs in the first chain, includes a third bonding pad in the first semiconductor structure and a fourth bonding pad in the second semiconductor structure. A first misalignment distance between the first and second bonding pads is greater than a second misalignment distance between the third and fourth bonding pads.

### CROSS-REFERENCE TO RELATED APPLICATIONS

This application claims priority to Chinese Application No. 202511705100.9, filed on Nov. 19, 2025, and to International Application No. PCT/CN2025/091123, filed on Apr. 25, 2025, which are incorporated herein by reference in their entirety.

### TECHNICAL FIELD

The present disclosure generally relates to semiconductor technology, and more particularly, to a semiconductor device comprising a structure of bonding pads embedded within a chip.

### BACKGROUND

With the increasing demands for storage capacity and performance, three-dimensional (3D) memory devices, such as 3D NAND flash memory, 3D dynamic random access memory (DRAM) and high bandwidth memory (HBM), have been widely used. To optimize performance of 3D memory devices and other types of semiconductor devices, semiconductor bonding technologies have also been developed. In an example, two chips are separately formed and then bonded together using wafer bonding technology.

However, the chips may be bonded without appropriate alignment. During the bonding process, various factors may lead to alignment deviations. These factors include, but are not limited to, differences in wafer deformation, alignment marks and equipment accuracy, vacuum and pressure control, and thermal expansion and contraction, etc. These misalignments may result in alignment deviations at the bonding interface, and the alignment quality of bonding directly affects production reliability and device yield.

### SUMMARY

Aspects of the present disclosure provide a semiconductor device, and a method for manufacturing the same, to improve the misalignment detection and the reliability of the semiconductor device.

In a first aspect of the present disclosure, example embodiments provide a semiconductor device comprising a first semiconductor structure and a second semiconductor structure bonded over the first semiconductor structure, a first chain including a plurality of first bonding pad pairs each including a first bonding pad in the first semiconductor structure and a second bonding pad in the second semiconductor structure that are bonded together, and a second bonding pad pair that does not belong to the first chain and is adjacent to at least one of the first bonding pad pairs in the first chain, the second bonding pad pair including a third bonding pad in the first semiconductor structure and a fourth bonding pad in the second semiconductor structure, wherein a first misalignment distance between the first bonding pad and the second bonding pad is larger than a second misalignment distance between the third bonding pad and the fourth bonding pad.

In some examples, the semiconductor device further comprises a third bonding pad pair that does not belong to the first chain and is adjacent to the second bonding pad pair, the third bonding pad pair including a fifth bonding pad in the first semiconductor structure and a sixth bonding pad in the second semiconductor structure, wherein a first difference between the first and second misalignment distances is greater than a second difference between a third misalignment distance between the fifth bonding pad and the sixth bonding pad and the second misalignment distance.

In some examples, each bonding pad in the first and second bonding pad pairs has a substantially equal diameter, and a difference between the first and second misalignment distances is greater than one tenth of the diameter.

In some examples, the first misalignment distance is greater than or equal to sixty percent of the diameter, and the second misalignment distance is less than sixty percent of the diameter.

In some examples, the first and second semiconductor structures each further comprise a dielectric bonding region in which a dielectric material includes carbon-doped silicon nitride.

In some examples, the first bonding pad pair is located between a seal ring and the second bonding pad air.

In some examples, the adjacent first bonding pad pairs in the first chain are connected via a conductive path within either of the first or the second semiconductor structures such that the first bonding pad pairs in the first chain are connected in series.

In some examples, the adjacent first bonding pad pairs in the first chain are connected through a first interconnect layer in the first semiconductor structure that connects the first bonding pads and a second interconnect layer in the second semiconductor structure that connects the second bonding pads.

In some examples, the first semiconductor structure includes a first semiconductor component and the second semiconductor structure includes a second semiconductor component, and the first semiconductor component is connected to the second semiconductor component via the second bonding pad pair.

In some examples, the semiconductor device further comprises a second chain including a plurality of first bonding pad pairs, each of the first and second chains including first bonding pad pairs having misalignments in a same direction, the first bonding pad pairs within each chain being connected in series, and the first and second chains being isolated from each other.

In some examples, the first misalignment distance is along a plane where the first bonding pad and the second bonding pad are bonded together.

In some examples, the first and second semiconductor structures are of the same type.

In a second aspect of the present disclosure, example embodiments provide a semiconductor device comprising a first semiconductor structure and a second semiconductor structure bonded over the first semiconductor structure, a chain including a plurality of first bonding pad pairs each including a first bonding pad in the first semiconductor structure and a second bonding pad in the second semiconductor structure that are bonded together, and a second bonding pad pair that does not belong to the chain and is adjacent to a bonding pad pair in the chain, wherein the first bonding pad pair has a first misalignment vector indicating a first misalignment between the first and second bonding pads, the second bonding pad pair has a second misalignment vector indicating a second misalignment between the third and fourth bonding pads, and a vector difference between the first and second misalignment vectors is non-zero.

In some examples, the first semiconductor structure includes a fifth bonding pad and the second semiconductor structure includes a sixth bonding pad, the fifth bonding pad and the sixth bonding pad are bonded together to form a third bonding pad pair that does not belong to the chain and is adjacent to the second bonding pad pair, wherein a vector difference between the first and second misalignment vectors is greater than a vector difference between the third and second misalignment vectors in terms of vector length.

In some examples, the first and second semiconductor structures each further comprise a dielectric bonding region in which a dielectric material includes carbon-doped silicon nitride.

In some examples, the first bonding pad pair is located between a seal ring and the second bonding pad pair.

In some examples, each bonding pad in the first and second bonding pad pairs has a substantially equal diameter, and a vector difference between the first and second misalignment vectors is greater than one tenth of the diameter.

In some examples, a length of the first misalignment vector is greater than or equal to sixty percent of the diameter, and a length of the second misalignment vector is less than sixty percent of the diameter.

In some examples, the first semiconductor structure comprises a memory cell array and the second semiconductor structure comprises a periphery circuit of the memory cell array.

In a third aspect of the present disclosure, example embodiments provide a method for manufacturing a semiconductor device, the method comprising forming a first semiconductor structure including first bonding pads and a second bonding pad, forming a second semiconductor structure including third bonding pads and a fourth bonding pad, and bonding the first semiconductor structure over the second semiconductor structure, wherein the first bonding pads and the third bonding pads are bonded together respectively to form first bonding pad pairs connected to form a chain, at least two of the first bonding pad pairs in the chain being connected via a conductive path within either of the first or the second semiconductor structures, and the second bonding pad and the fourth bonding pad being bonded together to form a second bonding pad pair that does not belong to the chain, wherein a first misalignment distance between the first bonding pad and the third bonding pad is larger than a second misalignment distance between the second bonding pad and the fourth bonding pad.

In some examples, the first semiconductor structure includes a fifth bonding pad and the second semiconductor structure includes a sixth bonding pad, the fifth bonding pad and the sixth bonding pad are bonded together to form a third bonding pad pair that does not belong to the chain and is adjacent to the second bonding pad pair, the third bonding pad pair having a third misalignment distance, wherein a difference between the first and second misalignment distances is greater than a difference between the third and second misalignment distances.

In some examples, the first and second semiconductor structures each further comprise a dielectric bonding region in which a dielectric material includes carbon-doped silicon nitride.

In some examples, the first bonding pad pair is located between a seal ring and the second bonding pad pair.

In some examples, each bonding pad in the first and second bonding pad pairs has a substantially equal diameter, and a difference between the first and second misalignment distances is greater than one tenth of the diameter.

In some examples, the first misalignment distance is greater than or equal to sixty percent of the diameter, and the second misalignment distance is less than sixty percent of the diameter.

### DESCRIPTION OF DRAWINGS

Various embodiments of this disclosure that are proposed as examples will be described in detail with reference to the following figures, wherein like numerals reference like elements, and wherein:

FIG. 1 illustrates a block diagram of an exemplary system having a memory device, according to some aspects of the present disclosure.

FIG. 2 illustrates a diagram of an exemplary memory card having a memory device, according to some aspects of the present disclosure.

FIG. 3 illustrates a diagram of an exemplary solid-state drive (SSD) having a memory device, according to some aspects of the present disclosure.

FIG. 4 illustrates a schematic diagram of an exemplary memory device including peripheral circuits, according to some aspects of the present disclosure.

FIG. 5 illustrates a schematic sectional view of a memory device, according to some aspects of the present disclosure.

FIG. 6 illustrates a schematic sectional view of another memory device, according to some aspects of the present disclosure.

FIG. 7 illustrates a block diagram of a first semiconductor structure and a second semiconductor structure after being bonded together in a face-to-face orientation to form a semiconductor device, according to some aspects of the present disclosure.

FIG. 8 illustrates a schematic sectional view of a portion of a semiconductor device with a bonding pad pairs in hybrid bonding layers of FIG. 7, showing a designed misalignment Dd.

FIG. 9 illustrates a schematic top view of bonding pad pairs in accordance with an example of the present disclosure.

FIG. 10 illustrates a schematic sectional view of a portion of a semiconductor device with two adjacent bonding pad pairs showing different misalignment distances D1 and D2.

FIG. 11A illustrates a schematic top view of two adjacent bonding pad pairs showing different misalignment distances D1 and D2.

FIG. 11B illustrates schematic top views of two adjacent bonding pad pairs showing different misalignment vectors V1 and V2, and a vector difference VD.

FIGS. 12A-12E illustrate schematic top views of five example arrangements of bonding pad pairs in accordance with other examples of the present disclosure.

FIG. 13 illustrates a simplified schematic sectional view of a first semiconductor structure and a second semiconductor structure bonded together in a face-to-face orientation to form a chain in a semiconductor device, where adjacent bonding pad pairs are interconnected through the substrate.

FIG. 14 illustrates a simplified schematic sectional view of a first semiconductor structure and a second semiconductor structure bonded together in a face-to-face orientation to form a chain in a semiconductor device, where adjacent bonding pad pairs are interconnected through the interconnect layers.

FIG. 15 illustrates a flow chart of a method for manufacturing a semiconductor device.

### DETAILED DESCRIPTION OF EMBODIMENTS

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment”, “an embodiment”, “an example embodiment”, “some embodiments”, “an example” etc., indicate that the embodiment described can include a particular feature, structure, or characteristic, but every embodiment can not necessarily include the particular feature, structure, or characteristic. Moreover, such phrases do not necessarily refer to the same example. Further, when a particular feature, structure, or characteristic is described in connection with an example, it would be within the knowledge of a person skilled in the pertinent art to affect such feature, structure, or characteristic in connection with other examples whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a”, “an”, or “the”, again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on”, “above”, and “over” in the present disclosure should be interpreted in the broadest manner such that “on” not only means “directly on” something, but also includes the meaning of “on” something with an intermediate feature or a layer there between. Moreover, “above” or “over” not only means “above” or “over” something, but can also include the meaning it is “above” or “over” something with no intermediate feature or layer there between (i.e., directly on something).

Further, spatially relative terms, such as “beneath”, “below”, “lower”, “above”, “upper”, and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The device can be otherwise oriented (rotated 90 degrees or at other orientations) and the spatially relative descriptors used herein can likewise be interpreted accordingly.

As used herein, the term “layer” refers to a material portion including a region with a thickness. A layer can extend over the entirety of an underlying or overlying structure, or can have an extent less than the extent of an underlying or overlying structure. A layer can extend horizontally, vertically, and/or along a tapered surface. A layer can include multiple layers. For example, an interconnect layer can include one or more conductive and contact layers (in which pads, interconnect lines, and/or vertical interconnect accesses (VIAs) are formed) and one or more dielectric layers.

In the present disclosure, the term “horizontal/horizontally/transverse” means nominally parallel to a lateral surface of a substrate. In the present disclosure, the term “each” may not only necessarily mean “each of all”, but can also mean “each of a subset”.

As used herein, a “wafer” is a piece of semiconductor material into which and/or on which semiconductor devices are built, and which may undergo various processes before being diced into dies.

Although terms such as first, second, third, etc., may be used to describe diverse constituent elements, such constituent elements are not limited by the terms. The terms are used only to discriminate a constituent element from other constituent elements in the specification. These terms do not intend to sort an order of the constituent elements and/or an order of the manufacturing process of the constituent elements.

In the drawings, an X-Y-Z orthogonal coordinate system is used for convenience of description, in which a Z direction defines a stacking direction along which the first and the second semiconductor structures are stacked. An X direction and a Y direction are orthogonal to the Z direction, also referred as transverse directions.

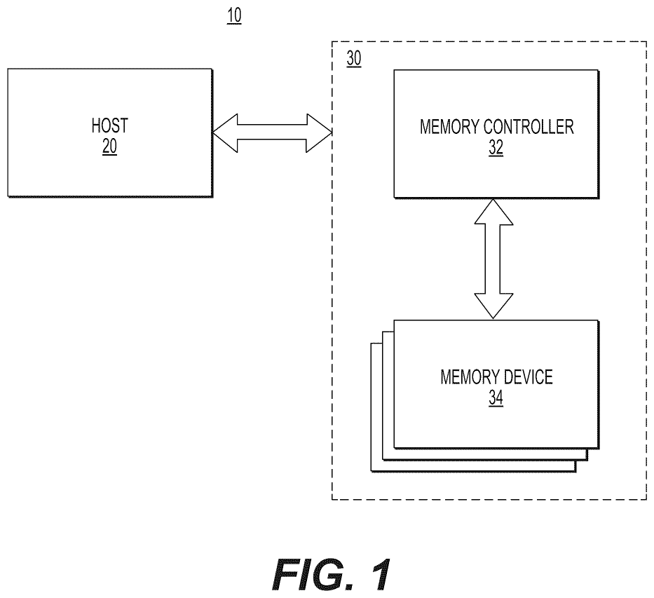

FIG. 1 illustrates a block diagram of an exemplary system having a memory device, according to some aspects of the present disclosure. The system 10 may represent a wide range of electronic devices such as mobile phones, desktop computers, laptops, tablets, vehicle control units, gaming consoles, printers, navigation systems, wearable electronics, smart sensors, virtual reality (VR) headsets, augmented reality (AR) devices, or other suitable devices with integrated storage. As shown in FIG. 1, system 10 includes the host 20 and a memory system 30 composed of one or more memory devices 34 and a memory controller 32. Host 20 can be any processor within an electronic device, including a central processing unit (CPU) or a system-on-chip (SoC) such as an application processor (AP), which communicates with the memory system 30 to send or retrieve data.

The memory device 34 can include various types of memory, such as NAND flash memory, vertical NAND flash, DRAM, ferroelectric RAM (FRAM), magneto resistive RAM (MRAM), phase-change RAM (PCRAM), resistive RAM (RRAM), and nano RAM (NRAM), among others.

Memory controller 32 connects the memory device 34 to the host 20 and is responsible for managing memory operations. It can control data read, erase, and write actions, and perform tasks such as bad block management, garbage collection, logical-to-physical address mapping, and wear leveling. In some implementations, memory controller 32 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 32 is designed for operating in a high duty-cycle environment SSDs or embedded multi-media-cards (eMMCs) used as data storage for mobile devices, such as smartphones, tablets, laptop computers, etc., and enterprise storage arrays. Memory controller 32 can be configured to control operations of memory device 34, such as read, erase, and program operations. Memory controller 32 can also be configured to manage various functions with respect to the data stored or to be stored in memory device 34 including, but not limited to bad-block management, garbage collection, logical-to-physical address conversion, wear leveling, etc.

In some implementations, memory controller 32 is further configured to process error correction codes (ECCs) with respect to the data read from or written to memory device 34. Any other suitable functions may be performed by memory controller 32 as well, for example, formatting memory device 34. Memory controller 32 can communicate with an external device (e.g., host 20) according to a particular communication protocol. For example, memory controller 32 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

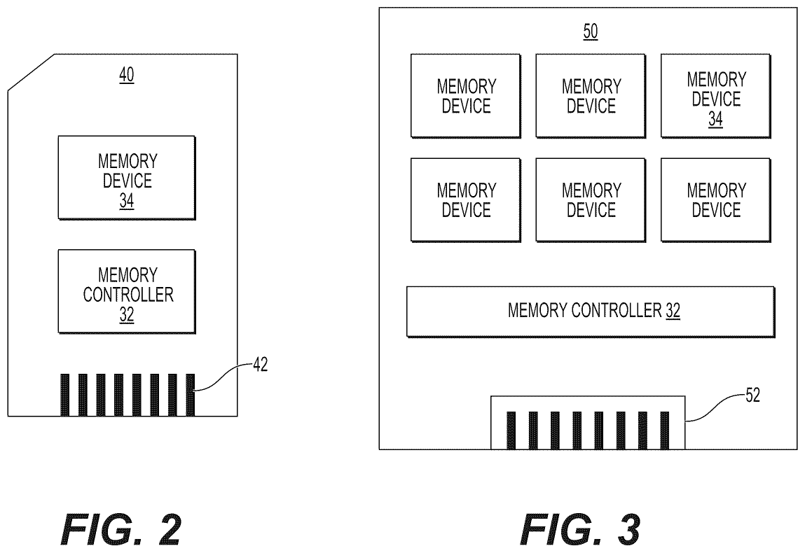

FIG. 2 illustrates a diagram of an exemplary memory card having a memory device, according to some aspects of the present disclosure. As illustrated in FIG. 2, the memory controller 32 and memory device 34 may be packaged together into a single memory card 40, which could be a PCMCIA card, CF card, smart media card, memory stick, MMC, SD card, UFS card, etc. The memory card 40 includes a connector 42 for interfacing with a host device. Memory controller 32 and one or more memory devices 34 can be integrated into various types of storage devices, for example, be included in the same package, such as a universal Flash storage (UFS) package or an eMMC package. That is, memory system 30 can be implemented and packaged into different types of end electronic products. In one example as shown in FIG. 2, memory controller 32 and a single memory device 34 may be integrated into a memory card 40. Memory card 40 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 40 can further include a memory card connector 42 coupling memory card 40 with a host (e.g., host 20 in FIG. 1).

FIG. 3 illustrates a diagram of an exemplary solid-state drive (SSD) having a memory device, according to some aspects of the present disclosure. In another configuration shown in FIG. 3, the memory controller 32 and multiple memory devices 34 may be integrated into a solid-state drive (SSD) 50, which includes an SSD connector 52 for interfacing with the host. Compared to memory cards, SSDs often offer higher capacity and faster data transfer speeds.

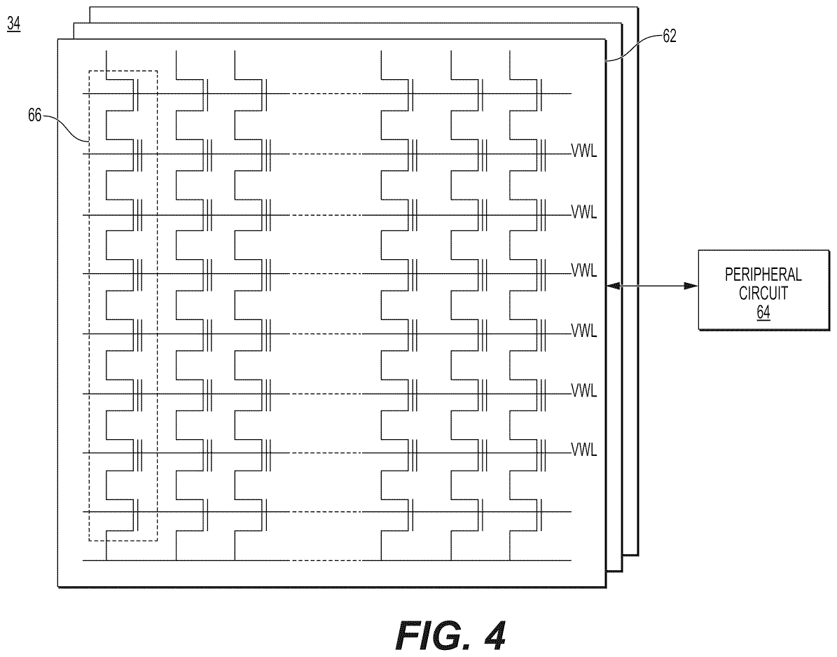

FIG. 4 illustrates a schematic diagram of an exemplary memory device including peripheral circuits, according to some aspects of the present disclosure. Memory device 60 can be an example of memory device 34 in FIG. 1A. The memory device 60 can include a memory cell array 62 and peripheral circuits 64 coupled to memory cell array 62. Memory cell array 62 can be a NAND Flash memory cell array in which memory cells are provided in the form of an array of NAND memory strings 66 each extending vertically above a substrate (not shown). In some implementations, each NAND memory string 66 includes a plurality of memory cells coupled in series and stacked vertically. Each memory cell can hold a continuous, analog value, such as an electrical voltage or charge, that depends on the number of electrons trapped within a region of the memory cell. Each memory cell can be either a floating gate type of memory cell including a floating-gate transistor or a charge trap type of memory cell including a charge-trap transistor.

In some implementations, each memory cell is a single-level cell (SLC) that has two possible memory states and thus, can store one bit of data. For example, the first memory state “0” can correspond to a first range of voltages, and the second memory state “1” can correspond to a second range of voltages. In some implementations, each memory cell is a multi-level cell (MLC) that is capable of storing more than a single bit of data in more than four memory states. For example, the MLC can store two bits per cell, three bits per cell (also known as triple-level cell (TLC)), or four bits per cell (also known as a quad-level cell (QLC)). Each MLC can be programmed to assume a range of possible nominal storage values. In one example, if each MLC stores two bits of data, then the MLC can be programmed to assume one of three possible programming levels from an erased state by writing one of three possible nominal storage values to the cell. A fourth nominal storage value can be used for the erased state.

As shown in FIG. 4, the peripheral circuit 64 can couple to the memory cell array through a bit line (BL), a word line (WL), a source select gate (SSG), and a drain select gate (DSG). The peripheral circuitry may include any suitable analog, digital, and mixed-signal circuitry for facilitating the associated operation of the array of memory cells by applying voltage signals and/or current signals to and sensing voltage signals and/or current signals from each target memory cell via a bit line, word line, source, SSG, or DSG, etc. In addition, the peripheral circuits may include various types of peripheral circuits formed using metal-oxide-semiconductor (MOS) technology. The peripheral circuit 64 can include components such as page buffers, row and column decoders, sense amplifiers, word line drivers, input/output (I/O) circuits, voltage generators or regulators, charge pumps, control logic, registers, interfaces, data buses, and various active or passive elements including transistors, resistors, diodes, capacitors, or sub-circuits thereof.

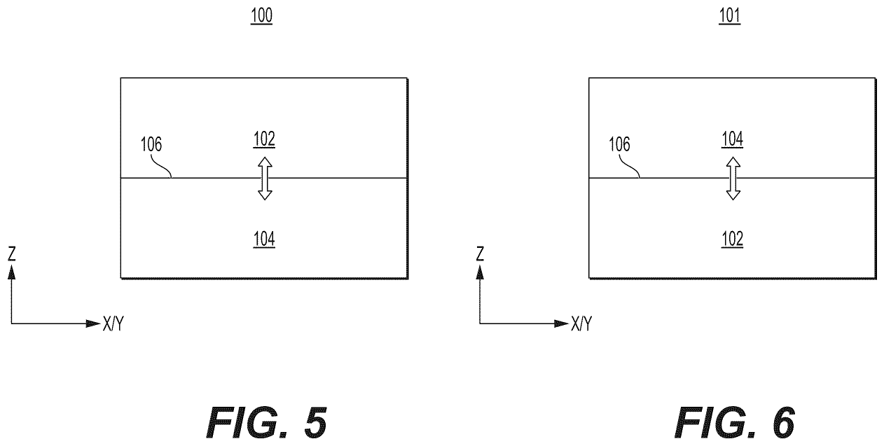

FIG. 5 illustrates a schematic sectional view of a semiconductor device 100, according to some aspects of the present disclosure. FIG. 6 illustrates a schematic sectional view of another semiconductor device 101, according to some aspects of the present disclosure. The semiconductor device 100 or 101 can each include a first semiconductor structure 102 and a second semiconductor structure 104 stacked together. The first semiconductor structure 102 and the second semiconductor structure 104 may be fabricated on separate substrates and later joined to form an integrated device.

For example, the first semiconductor structure 102 is a memory cell array and the second semiconductor structure 104 is a peripheral circuit. The peripheral circuit is configured to support memory operations and may include digital, analog, or mixed-signal circuits. In some implementations, the peripheral circuit is formed using CMOS technology with advanced logic process nodes (e.g., 90 nm down to 2 nm). The memory cell array may be composed of memory cells implemented with switching and selection transistors. While the description uses a DRAM cell array as a representative example for illustration purposes, other memory technologies can also be used in other embodiments. In some embodiments, when hybrid bonding is applied to memory arrays and peripheral circuits, the memory arrays may also include NAND flash arrays or other types of non-volatile memory arrays. These include phase-change memory (PCM), static random-access memory (SRAM), ferroelectric RAM (FRAM), resistive RAM (RRAM), magnetic RAM (MRAM), spin-transfer torque (STT) memory arrays, or combinations thereof. A common architecture is the one-transistor-one-capacitor (1T1C) cell. Other cell structures may also be employed, such as one-transistor-zero-capacitor (1T0C), one-transistor-multiple-capacitor (1TnC), or two-transistor-multiple-capacitor (2TnC) configurations, depending on the specific DRAM architecture. In some embodiments, hybrid bonding may be applied in multi-chip stacking scenarios, such as high-bandwidth memory (HBM) or hybrid bonding flash (HBF). In such cases, multiple chips may be stacked, each chip comprising both memory arrays and associated peripheral circuits, with hybrid bonding formed between the stacked chips. In some embodiment, hybrid bonding may be formed between a memory chip and a logic control chip, thereby enabling efficient integration of memory and logic functions within a single package. The present disclosure is not limited to the specific examples described herein but is broadly applicable to a wide range of hybrid bonding applications involving memory arrays, peripheral circuits, and chip stacking technologies.

Furthermore, the spatial orientation of the first and second semiconductor structures 102 and 104 is defined relative to X, Y, and Z axes, as indicated in FIGS. 5 and 6. The semiconductor device 100 or 101 features two lateral surfaces along the X-Y plane for each of the semiconductor structures 102 and 104: a top surface where devices are formed on a substrate and a bottom surface on the substrate's backside. The Z-axis runs perpendicular to the X-Y plane. In this context, terms like “above,” “below,” or “on” refer to positions along the Z-axis, with respect to the substrate being located at the bottom-most level of the device. This directional terminology is consistently applied throughout the disclosure.

As illustrated in FIG. 5, the first and second semiconductor structures 102 and 104 are joined at a bonding interface 106. The bonding interface 106 is positioned between the first and second structures 102 and 104. This vertical stacking approach allows the two structures to be fabricated independently. thereby enabling parallel fabrication. The bonding interface 106 includes numerous interconnects (e.g., bonding pads), enabling short-distance, high-speed communication between the two structures. In contrast, traditional chip-to-chip connections over circuit boards are typically longer and slower. The vertical integration of these layers not only minimizes data path delays and power consumption but also enables more compact chip dimensions and higher memory density. The interconnects at the bonding interface facilitate the transfer of signals between the memory array and the peripheral circuits in some implementations.

The vertical arrangement of the two semiconductor structures 102 and 104 can be flexible. For instance, the semiconductor device 101 in FIG. 6 is an alternative configuration of the semiconductor device 100. In the semiconductor device 101, the second semiconductor structure 104 containing the peripheral circuits is positioned on top of the second semiconductor structure 102. The semiconductor structure includes the memory cell array of the first semiconductor structure 102. Despite the reversed stacking order, the two layers are still joined vertically via the bonding interface 106. This interface is established using hybrid bonding techniques. Hybrid bonding allows direct dielectric-to-dielectric and metal-to-metal contact, and is commonly referred to as metal/dielectric hybrid bonding. This method avoids intermediate materials like solder or adhesives and supports copper-to-copper and silicon oxide-to-silicon oxide bonding.

In both configurations in FIGS. 5-6, data or control communication between the memory cell array and the peripheral circuit occurs through the bonding interface 106.

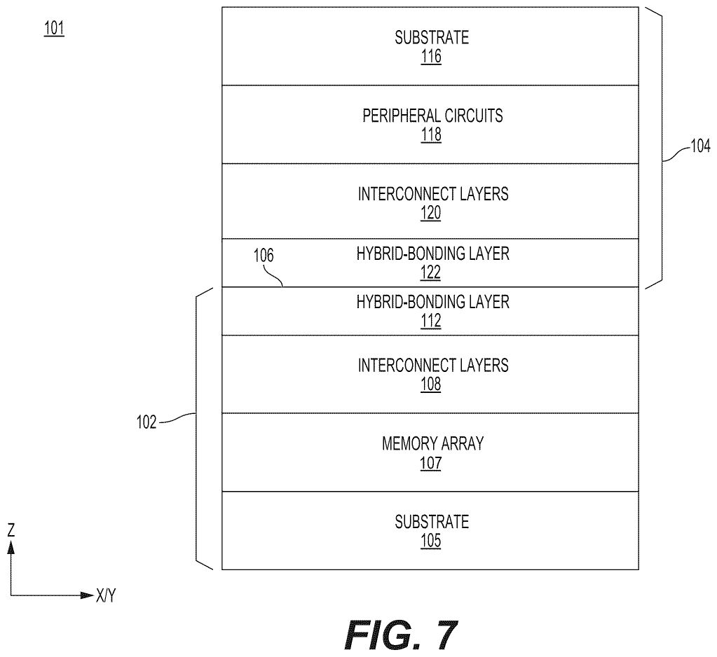

FIG. 7 illustrates a block diagram of the first semiconductor structure 102 (e.g., memory cell array) and the second semiconductor structure 104 (e.g., peripheral circuit) after being bonded together in a face-to-face orientation to form the semiconductor device 101, according to some aspects of the present disclosure. The first semiconductor structure 102 includes a first substrate 105, a memory array 107, a first interconnect layer 108, and a first hybrid-bonding layer 112 (or first bonding layer 112). The semiconductor structure 104 includes a second substrate 116, a peripheral circuit 118, a second interconnect layer 120, and a second hybrid-bonding layer 122 (or second bonding layer 122). These layers are stacked together as shown in FIG. 7. The first semiconductor structure 102 includes first bonding pads (not shown) and the second semiconductor structure 104 includes second bonding pads (not shown). In this bonded configuration of FIG. 7, one or more first bonding pads of the hybrid-bonding layer 112 are in electrical contact with a corresponding one or more second bonding pads of the second hybrid-bonding layer 122, e.g., via hybrid bonding. Additional details of the first and second bonding pads are described below.

Generally, hybrid bonding refers to a wafer-level or die-level bonding technique that combines both dielectric-to-dielectric bonding and metal-to-metal bonding within the same interface. In this process, interlayer dielectrics (e.g., oxides) can be brought into contact and bonded, and direct metallic connections (e.g., copper-to-copper) can be formed across the bonded interface. This approach enables fine-pitch interconnects, reduced parasitic, and improved electrical and mechanical performance compared to conventional bonding methods such as thermocompression or solder-based bonding.

The bonding layer 112 or 122 can include a plurality of bonding contact structures embedded in a dielectric layer. The bonding contact structures include metal lines, vias, and bonding pads. The dielectric layer may include one or multiple layers of dielectric materials.

It is noted that the orientation of the semiconductor device 101, shown in FIGS. 6-7, with the first semiconductor structure on the bottom and the second semiconductor structure on top is illustrative and not limiting. That is, the semiconductor device 101, can be oriented such the that second semiconductor structure 104 is at the bottom with the bonding layer 122 as its top layer, and the first semiconductor structure 102 is on top with the bonding layer 112 as its bottom layer. In this alternative orientation, the memory array is in the top portion of the semiconductor device 101. In various manufacturing processes, after the first semiconductor structure and the second semiconductor structure are bonded together, a substrate may be partially or completely removed from at least one of the semiconductor structures and a new semiconductor layer formed thereon.

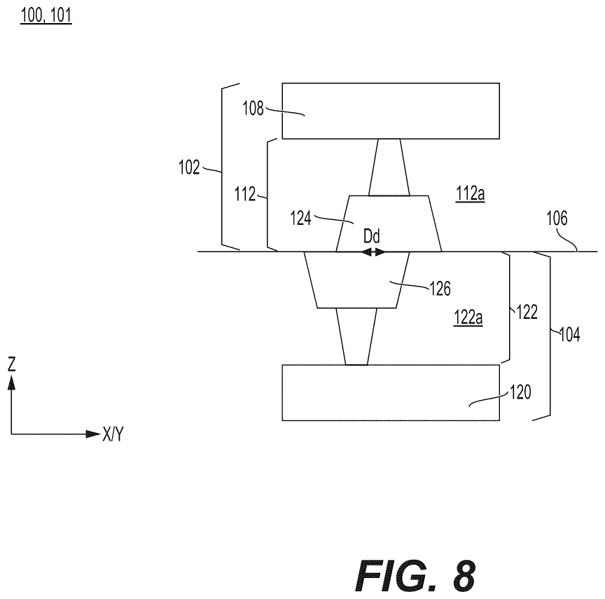

FIG. 8 illustrates a schematic sectional view of a portion of a semiconductor device 100 or 101 with a bonding pad pair embedded in hybrid bonding layers 112 and 122 of FIG. 7. The semiconductor device 100 or 101 includes a first semiconductor structure 102 and a second semiconductor structure 104. In some embodiments, the first semiconductor structure 102 includes a first interconnect layer 108 and a first bonding layer 112. The first bonding layer 112 includes a first dielectric bonding region 112a. A first bonding pad 124 is formed in the first bonding layer 112. In some embodiments, the second semiconductor structure 104 includes a second interconnect layer 120 and a second bonding layer 122. The second bonding layer 122 includes a second dielectric bonding region 122a. A second bonding pad 126 is formed in the second bonding layer 122. The bonding pads 124 and 126 may have various shapes at the bonding interface 106.

In some embodiments, the first semiconductor structure 102 and the second semiconductor structure 104 are bonded, and the first bonding pad 124 and the second bonding pad 126 are electrically connected through direct contact. The bonding may occur in a face-to-face configuration in which active or metallization layers of both structures are aligned and joined. In such a configuration, the first bonding pad 124 and the corresponding second bonding pad 126 together form a bonding pad pair. In some embodiments, the first and second bonding pads 124 and 126 may form an aligned bonding pad pair (not shown), that is, the first bonding pad 124 and the second bonding pad 126 completely overlap.

In some embodiments, as illustrated in FIG. 8, the first and second bonding pads 124 and 126 may form a misaligned bonding pad pair. The misaligned bonding pad pair has a designed misalignment Dd between the first and second bonding pads 124 and 126. Because the first and second bonding pads 124 and 126 are in direct electrical contact, the resistance of the bonding pad pair varies with the contact area between the pads. As the misalignment increases, the overlap contact area decreases, which results in a higher resistance of the bonding pad pair. Conversely, as the overlap area increases, the resistance decreases. This correlation between contact area and resistance allows the designed misalignment Dd to be measured, and the resistance detected thereby reflects the misalignment between the first semiconductor structure 102 and the second semiconductor structure 104.

The designed misalignment Dd may be intentionally designed to be larger than a regular bonding tolerance so that the misalignment of the bonding pad pairs can be effectively detected. For example, the designed misalignment Dd can be larger than one tenth of the critical dimension of the first or second bonding pads 124 or 126, or one tenth of the diameter of the first or second bonding pads 124 or 126 when the first or second bonding pad 124 or 126 are round. In some examples, the designed misalignment Dd can be one tenth to eight tenths of the critical dimension of the first or second bonding pad 124 or 126. Such a misalignment in the bonding pad pairs 114 is deliberately designed to enhance detection of potential misalignment during the bonding process, as the predetermined misalignment amplifies any misalignment that may occur during bonding.

In some embodiments, the designed misalignment Dd may exceed alignment tolerances. For example, the alignment tolerance may be defined to be 60% of a diameter of a bonding pad having a circular shape. In such a scenario, the misaligned bonding pad pair may not form an adequate electrical connection, also reflects the misalignment between the first semiconductor structure 102 and the second semiconductor structure 104.

In some embodiments, the misalignment of the bonding pads 124 and 126 can alternatively be detected by measuring capacitance. The capacitance between the first and second bonding pads 124 and 126 is determined by the overlap contact area and the separation between the first and second bonding pads 124 and 126. As the designed misalignment Dd increases, the overlap area decreases, which leads to a reduction in capacitance. Conversely, as the overlap area increases, the capacitance correspondingly increases. Accordingly, the variation in capacitance provides another means for determining the designed misalignment Dd, and thus the relative alignment between the first semiconductor structure 102 and the second semiconductor structure 104.

The designed misalignment Dd can be a distance from a center of the first bonding pad 124 to a center of the second bonding pad 126. The center can be a geometric center of the respective bonding pad 124 or 126. For example, for a bonding pad having a rectangle or square shape at the bonding interface 106, the center is an intersection of diagonals. For a bonding pad having a shape of circle, the center is the center of the circle. The designed misalignment Dd can extend along any direction in the X-Y plane of the bonding interface 106.

In alternative embodiments, the bonding pad pair forms a misalignment vector that indicates a misalignment between the first bonding pad 124 and a corresponding second bonding pad 126, for example, from a center of the first bonding pad 124 to a center of the second bonding pad 126, or from an edge of the first bonding pad 124 to a corresponding edge of the second bonding pad 126.

In some embodiments, the first bonding layer 112 of the first semiconductor structure 102 includes the first bonding pad 124 disposed therein. The first interconnect layer 108 including interconnect lines is also illustrated. In this illustrative implementation, one or more first bonding pads 124 may be in electrical contact with an interconnect line of the first interconnect layer 108. The interconnect lines from the first interconnect layer 108 provide electrical pathways from, for example, the memory array of first semiconductor structure 102 to one or more first bonding pads 124. Similarly, the second bonding layer 122 of the second semiconductor structure 104 can include the second bonding pad 126 disposed therein. The second semiconductor structure 104 further includes the second interconnect layer 120 that includes interconnect lines. In this illustrative implementation, one or more second bonding pads 126 may be in electrical contact with an interconnect line of the second interconnect layer 120. Interconnect lines from the second interconnect layer 120 provide electrical pathways from, for example, the peripheral circuits of second semiconductor structure 104 to one or more second bonding pads 126.

In some embodiments, the first and second semiconductor structures 102 and 104 can each comprise a dielectric bonding region 112a or 122a. In some embodiments, the dielectric bonding regions 112a and 122a are located in the first and second bonding layers 112 and 122, respectively. In some embodiments, a dielectric material in the dielectric bonding regions can include carbon-doped silicon nitride (SiCN). For example, the dielectric bonding region 112a or 122a can each have a multi-layer structure. The multi-layer structure can include a layer of SiCN at the bonding interface 106. In some embodiments, the first and second semiconductor structures 102 and 104 can be connected (bonded) via the dielectric bonding region 112a, 122a.

In some embodiments, a semiconductor device 100 includes a first semiconductor structure 102 and a second semiconductor structure 104 bonded at a bonding interface 106, for example, through a hybrid bonding process. In some examples, the first and second semiconductor structures 102 and 104 are of the same type. In some examples, the semiconductor device 101 comprises a NAND stack, i.e., a stack of NAND flash memories. In some examples, both the first and the second semiconductor structures 102 and 104 include NAND flash memory. In some examples, the first and second semiconductor structures 102 and 104 are of different types. In an example, one of the first and the second semiconductor structures 102 and 104 may include a NAND flash memory and the other one may be a base die. In another yet example, the first semiconductor structure 102 includes a peripheral circuit, and the second semiconductor structure 104 includes a memory array structure (such as a memory array chip), or vice versa.

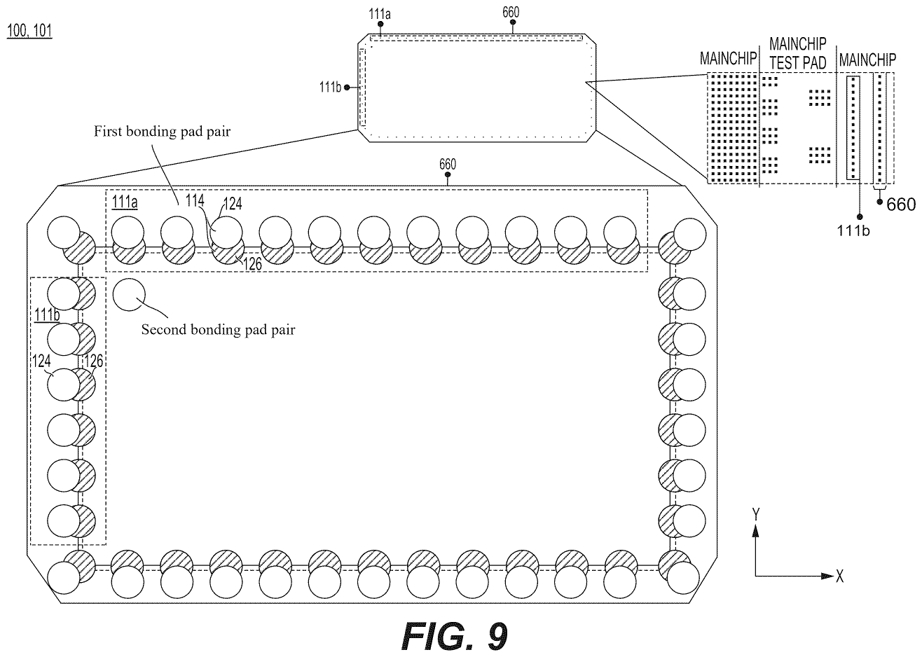

FIG. 9 illustrates a schematic top view of bonding pad pairs in accordance with an example of the present disclosure. The semiconductor device 100 or 101 may include a plurality of functional blocks in a main chip, a plurality of main chip test pads, and a seal ring 660. As illustrated in FIG. 9, in some embodiments, the semiconductor device 100 or 101 further comprises a first chain 111a including first bonding pad pairs and a second chain 111b including first bonding pad pairs. In some examples, each of the first bonding pad pair 114 is formed by the first bonding pad 124 disposed in the first semiconductor structure and a corresponding second bonding pad 126 disposed in the second semiconductor structure. The adjacent first bonding pad pairs 114 in the first or second chain 111a or 111b can be electrically coupled via a conductive path within the first and the second semiconductor structure. The first and second bonding pads 124 and 126 can form a misaligned pad pair, as shown in FIG. 9. As shown in FIG. 8, the misalignment between the first and second bonding pads 124 and 126 are intentionally designed as the designed misalignment Dd, and no bonding misalignment is illustrated in FIGS. 8-9.

In some embodiments, adjacent to the first bonding pad pair 114 in the first chain 111a, a second bonding pad pair is provided. This second pad pair is not part of the first chain 111a but is positioned nearby. The second bonding pad pair includes a third bonding pad formed in the first semiconductor structure 102 and a fourth bonding pad formed in the second semiconductor structure 104. The third and fourth bonding pads are bonded together.

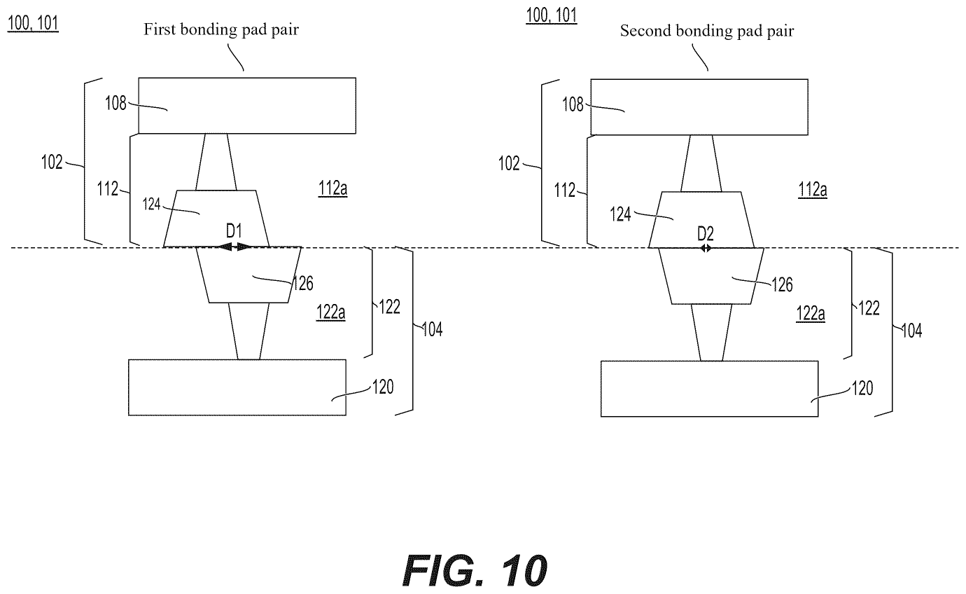

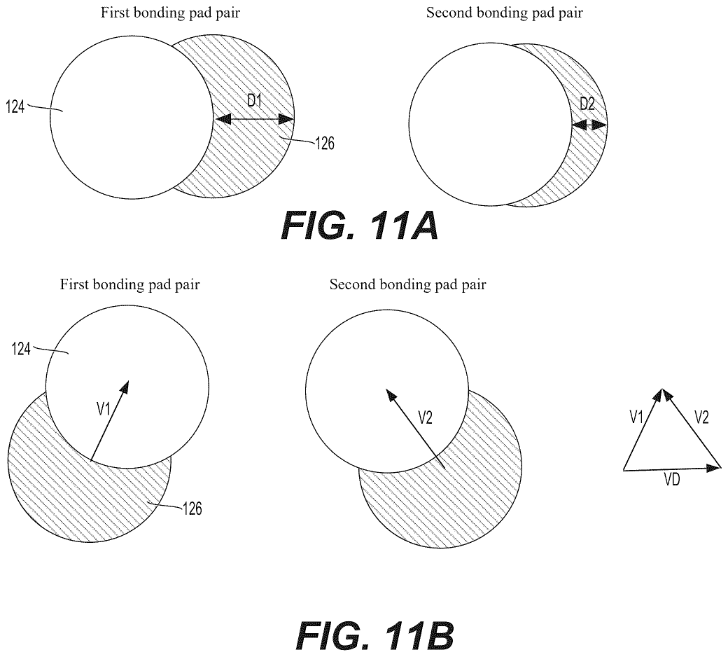

In some embodiments and further illustrated in FIGS. 10 and 11A, a first misalignment distance between the first bonding pad 124 and the second bonding pad 126 is larger than a second misalignment distance between the third bonding pad and the fourth bonding pad. Such relative differences in misalignment between adjacent pad pairs after bonding process can further facilitate identification of non-uniform displacement across the bonding interface. This enables detection of tilt or rotational misalignment trends that might not be apparent from a single pad pair, thereby improving accuracy in characterizing overall alignment.

In some examples, the semiconductor device 100 or 101 can include multiple segmentations not connected with each other. Each segmentation includes an individual chain. For example, the first chain 111a includes multiple first bonding pad pairs 114 and the second chain 111b includes multiple first bonding pad pairs 114, as shown in FIG. 9. In other examples, multiple first bonding pad pairs 114 in the first chain 111a can be aligned along a predetermined routing path and connected in series to form a chain-like test or signal path. In some embodiments, a group of neighboring first bonding pad pairs 114 in the first chain 111a can be connected in parallel. In some embodiments, multiple groups of such parallel-connected first bonding pad pairs 114 may be connected in series.

In some examples, the second chain 111b is presented, and multiple first bonding pad pairs are part of the second chain 111b. Each of the first or second chains 111a or 111b including bonding pad pairs having misalignments in the same direction along the X-Y plane (e.g., generally along the Y direction in FIG. 9), the first bonding pad pairs within each chain 111a or 111b are electrically connected in series, and the first and second chains 111a and 111b are electrically isolated from each other. In some examples, the misalignment direction of the first chain 111a is perpendicular to the misalignment direction of the second chain 111b. In some examples, the misalignment direction of the first chain 111a is opposite to the misalignment direction of the second chain 111b. In some examples, the electrical connection among bonding pad pairs in the first or second chain 111a or 111b can be connected in serial configuration (e.g., for resistance measurement), in parallel, or arranged using alternative connection schemes, provided that the measured electrical parameter exhibits a correlation to bonding alignment precision. The configuration of the bonding pad chain may therefore be adapted to different test methodologies, such as resistance, capacitance, or signal integrity measurements, depending on the design requirements and detection sensitivity to misalignment.

In some embodiments, all first bonding pad pairs 114 can be connected in series to form a single continuous test chain. In some embodiments, the bonding pad pairs 114 can be divided into multiple segmentations of test chains. Each segmentations of test chains includes bonding pad pairs having the same misalignment direction, and the pad pairs within one segmentations are connected in series, while different segmentations remain electrically isolated. During misalignment testing, if the resistance of any one segmentations exceeds a predetermined threshold, it can be determined that the chips are misaligned.

In some examples, the adjacent first bonding pad pairs 114 in the first chain 111a are electrically connected. In some examples, the connection is made through the first interconnect layer 108 and the second interconnect layer 120. In some examples, the first interconnect layer 108 in the first semiconductor structure 102 connects the first bonding pads 124, and the second interconnect layer 120 in the second semiconductor structure 104 connects the second bonding pads 126. In a similar way, the adjacent second bonding pad pairs can be electrically connected through the first interconnect layer 108 in the first semiconductor structure 102 that connects the third bonding pads and the second interconnect layer 120 in the second semiconductor structure 104 that connects the fourth bonding pads, or the adjacent third bonding pad pairs are electrically connected through the first interconnect layer 108 in the first semiconductor structure 102 that connects the fifth bonding pads and the second interconnect layer 120 in the second semiconductor structure 104 that connects the sixth bonding pads.

In some examples, any of the bonding pads 124 and 126 can be located at the peripheral portion. Although the first and second bonding pads 124 and 126 at the peripheral portion can be misaligned, e.g., aligned pad pairs, other sets of bonding pads at an inner portion can be adequately aligned to form reliable electrical contacts, e.g., aligned pad pairs. It should be appreciated that the inner portion shown herein may be closer to a geometric center of the semiconductor device 100 or 101, (and/or geometric centers of the first and second semiconductor structures 102 and 104) than the peripheral portion. The peripheral portion can be closer to the outer edge(s) of the semiconductor device 100 or 101, (and/or geometric centers of the first and second semiconductor structures 102 and 104) than the inner portion. In some examples, the first bonding pad pair can be located between the seal ring 660 and the second bonding pad pair. In some examples, the second bonding pad pair can be located between the first bonding pad pair and the third bonding pad pair.

As discussed above, the first semiconductor structure 102 can include a first semiconductor component, e.g., a memory array 107, and the second semiconductor structure 104 can include a second semiconductor component, e.g., peripheral circuits 118, and the first semiconductor component is connected to the second semiconductor component via the second bonding pad pair. The plurality of functional blocks in the main chip may be transistors such as complementary metal-oxide-semiconductor transistors, metal-oxide-semiconductor field-effect transistors, fin field-effect-transistors, the like, or a combination thereof. The plurality of functional blocks may cooperate together and provide a variety of functionalities such as logic, I/O, memory, analog circuits, and the like.

FIG. 10 illustrates a schematic sectional view of a portion of a semiconductor device 100 or 101 with two adjacent bonding pad pairs showing different misalignment distances D1 and D2. FIG. 11A illustrates a schematic top view of two adjacent bonding pad pairs showing different misalignment distances D1 and D2. FIGS. 10-11A further explain the misalignment relationship between two adjacent bonding pad pairs as a result of the misalignment of the first and second semiconductor structures 102 and 104. In some embodiments, the bonding pads 124 and 126 in the first and second bonding pad pairs have comparable physical dimensions (e.g., similar diameters in the X-Y plane), but the bonding pad pairs exhibit different levels of misalignment. In some examples, first and second misalignment distance D1 and D2 can be detected after bonding process. In some examples, the first misalignment distance D1 between the first bonding pad 124 and the second bonding pad 126 of the first bonding pad pair is larger than the second misalignment distance D2 between the adjacent first bonding pad 124 and the adjacent second bonding pad 126 of the second bonding pad pair. The detected different levels of misalignment provide a comparative reference, which enhances detection accuracy by distinguishing systematic shifts from random variations. This comparative measurement enables calibration of alignment across a broader bonding interface, improves yield by identifying localized misalignment defects, and facilitates process optimization by mapping alignment uniformity between multiple bonding pad pairs. Thus, the reliability of the semiconductor device 100 or 101 is improved.

FIG. 11B illustrates schematic top views of two adjacent bonding pad pairs showing different misalignment vectors V1 and V2, and a vector difference VD. In some examples, such as in FIG. 11B, the first bonding pad pair forms a first misalignment vector V1 that indicates a first misalignment between the first bonding pad and a corresponding second bonding pad. The second bonding pad pair forms a second misalignment vector V2 that indicates a second misalignment between the third bonding pad and the fourth bonding pad. A vector difference VD between the first and second misalignment vectors V1, V2 is non-zero. In some examples, a vector length of the vector difference VD between the first and second misalignment vectors V1 and V2 is greater than zero. Such a first or second misalignment vector V1 and V2, for example, can be formed from a center of the first or third bonding pad to a center of the second or fourth bonding pad, or from an edge of the first or third bonding pad to a corresponding edge of the second or fourth bonding pad. The use of misalignment vectors provides another two-dimensional analysis of displacement, thereby allowing identification of both magnitude and directional components of misalignment. This vector approach may improve alignment characterization, facilitates detection of rotational or angular misalignment, and provides more comprehensive data for process control and yield optimization. The first misalignment distance D1 or the first misalignment vector can extend in an X-Y plane corresponding to the bonding interface where the first bonding pad 124 and the second bonding pad 126 are bonded together.

In some embodiments, the first difference can be defined as the difference between the first misalignment distance D1 (between the first and second bonding pads) and the second misalignment distance D2 (between the third and fourth bonding pads). In some examples, the first difference between the first and second misalignment distances D1 and D2 is greater than 5%-15% of the diameter of any of the bonding pads 124 and 126 in the first and second bonding pad pairs in the X-Y plane, or the first difference is greater than 10% of the diameter of any of the bonding pads 124 and 126 in the X-Y plane. In some examples, the first misalignment distance D1 is greater than or equal to 60% of the diameter of any of the bonding pads 124 and 126 in the X-Y plane, and the second misalignment distance D2 is less than 60% of the diameter of any of the bonding pads 124 and 126 in the X-Y plane. In some examples, the first misalignment distance D1 is greater than or equal to 50% of the diameter of any of the bonding pads 124 and 126 in the X-Y plane, and the second misalignment distance D2 is less than 50% of the diameter of any of the bonding pads 124 and 126 in the X-Y plane. In some examples, the first misalignment distance D1 is greater than or equal to 70% of the diameter of any of the bonding pads 124 and 126 in the X-Y plane, and the second misalignment distance D2 is less than 70% of the diameter of any of the bonding pads 124 and 126 in the X-Y plane. In some examples, the first difference, the first misalignment distance D1, or the second misalignment distance D2 can be compared with an average diameter of any of the bonding pads 124 and 126, a maximum dimension of any of the bonding pads 124 and 126, a minimum dimension of any of the bonding pads 124 and 126, or a combination of the above.

In some embodiments, the device further includes a third bonding pad pair that does not belong to the first chain and is positioned adjacent to the second bonding pad pair. The third bonding pad pair includes a fifth bonding pad disposed in the first semiconductor structure 102 and a sixth bonding pad disposed in the second semiconductor structure 104. The fifth bonding pad and sixth bonding pad can be bonded together across the bonding interface. The third misalignment distance D3 is defined as the lateral offset between the center points of the fifth bonding pad and the sixth bonding pad. The third bonding pad pair, like the first and second pad pairs, may have a comparable physical pad geometry (e.g., shape and size) to facilitate controlled comparison of alignment across multiple pairs.

In some embodiments, the third bonding pad pair has a third misalignment vector, and a vector difference between the first and second misalignment vectors is greater than a vector difference between the third and second misalignment vectors in terms of vector length. Here, the vector difference can be defined as a length of the vector between the corresponding misalignment vectors.

In some embodiments, a first difference is defined as the difference between the first misalignment distance D1 and the second misalignment distance D2. A second difference is defined as the difference between the third misalignment distance D3 and the second misalignment distance D2. The first difference can be greater than the second difference. This configuration is useful in diagnosing alignment or deformation patterns across the bonding interface, for example, under edge-loading or thermal expansion effects during hybrid bonding processes.

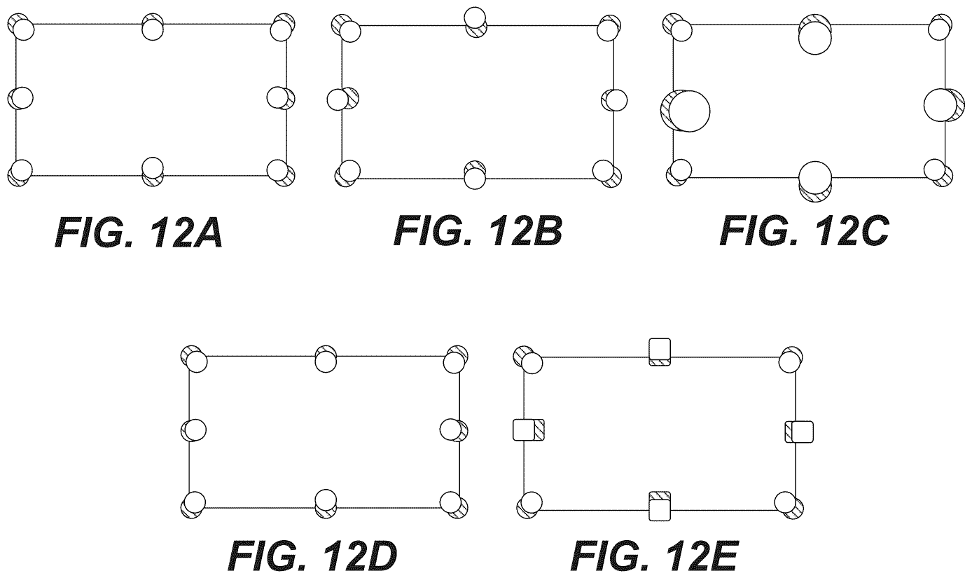

FIGS. 12A-12E illustrate schematic top views of five example arrangements of bonding pad pairs in accordance with other examples of the present disclosure. In some exemplary embodiments, as shown in FIG. 9, multiple first bonding pad pairs 114 may follow a consistent pattern in terms of area, shape, and positioning. For example, the pad pairs can be symmetrically distributed along the periphery of the semiconductor structures, with each bonding pad pair having uniform geometric dimensions (such as diameter), consistent shapes (e.g., circular or square), and uniform spacing.

However, the disclosure is not limited to such uniform configurations. In other embodiments, as illustrated in FIGS. 12A-12E, variations in the number, arrangement, size, or shape of the bonding pad pairs may be implemented. In one example, shown in FIG. 12A, the number of pad pairs is reduced to be suitable for simplified testing or for devices with limited surface area. FIG. 12B shows a configuration that the bonding pad pairs are arranged in an alternating pattern between inner and outer positions, allowing for increased sensitivity in detecting misalignment across different chip regions. FIG. 12C illustrates pad pairs with inconsistent sizes for evaluating alignment behavior across different feature scales. In another example, FIG. 12D shows a structure where a circular arrangement of bonding pad pairs is divided into multiple shorter chains, enabling localized or partitioned alignment evaluation. FIG. 12E presents pad pairs with different geometric shapes, such as a combination of circular and square pads, thus allow for multidimensional alignment testing within the same structure.

These variations in FIGS. 12A-12E provide flexibility in chip layout and bonding interface design, while still supporting the alignment characterization techniques disclosed herein. Regardless of the specific number or layout of pad pairs, the structure remains applicable so long as there exists a measurable correlation between the test parameters and the bonding alignment precision.

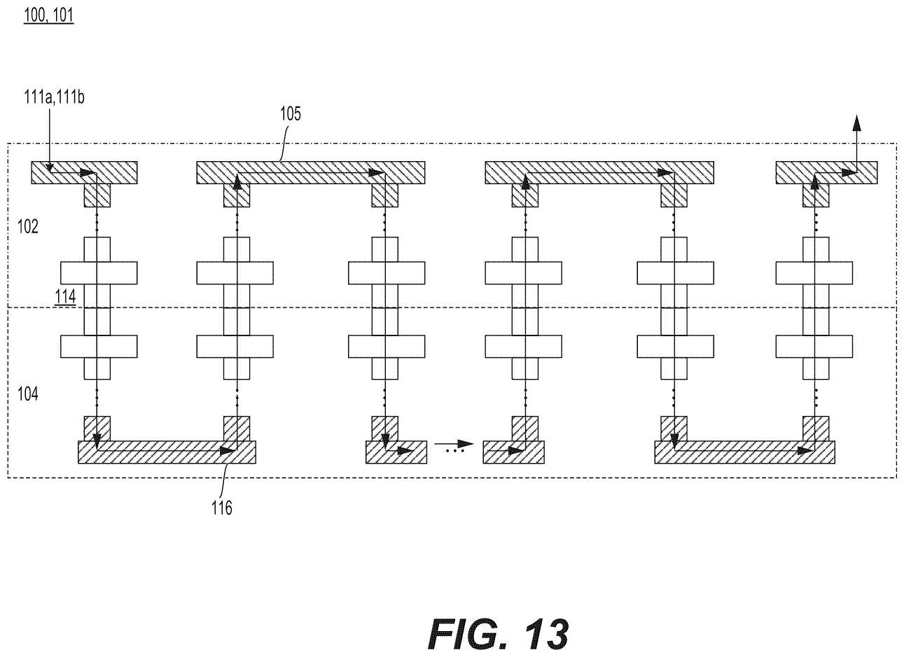

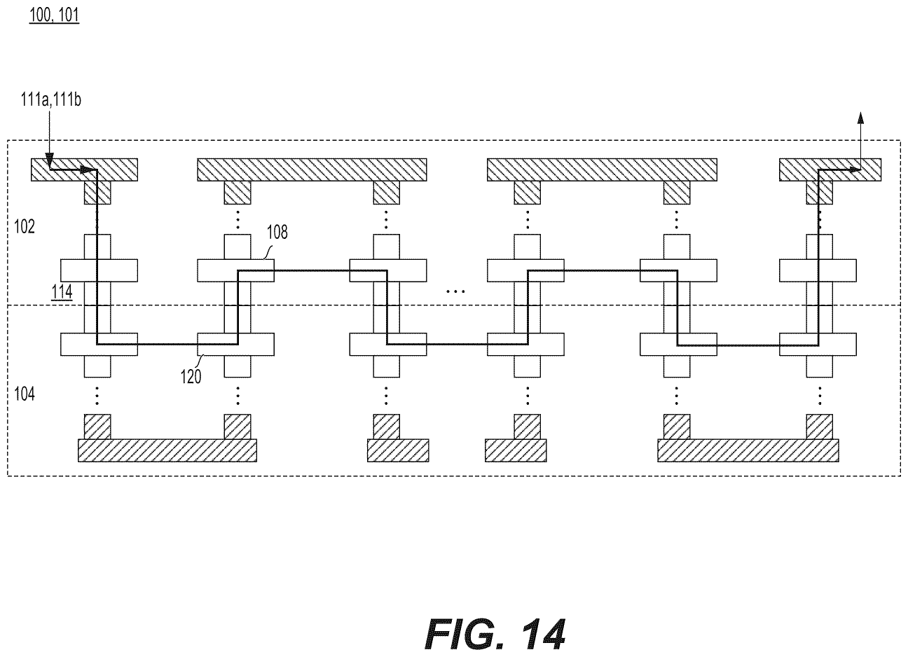

FIGS. 13-14 show schematic sectional views of examples of the first chain 111a. In these embodiments, each of the chains 111a or 111b can include any combination of the following: the first bonding pad pairs 114, the first substrate 105 of the first semiconductor structure 102 and the second substrate 116 of the second semiconductor structure 104, the first interconnect layer 108 of the first semiconductor structure 102 and the second interconnect layer 120 of the second semiconductor structure 104, and components connecting any of the two. The adjacent first bonding pad pairs 114 in the first chain 111a can be electrically coupled through the interconnect layer near the bonding interface or via a conductive path within either of the first or the second semiconductor structures, such that the bonding pad pairs in the first chain can be connected in series. In some examples, the first chain 111a of bonding pad pairs can be formed by physically non-adjacent bonding pad pairs. For instance, the bonding pad pairs in the chain 111a are not necessarily connected in immediate physical proximity; one or more pad pairs can be intentionally skipped between connected pad pairs. In some embodiments, the bonding pad pairs in the first chain 111a can be connected in parallel, or the bonding pad pairs in the first chain 111a can be partly disconnected. The misalignment between the bonding pad pairs is not specifically shown in FIGS. 13-14.

FIG. 13 illustrates a simplified schematic sectional view of a chain 111a or 111b in a semiconductor device 100 or 101 formed by bonding a first semiconductor structure 102 and a second semiconductor structure 104 in a face-to-face orientation. In this example, adjacent first bonding pad pairs 114 are interconnected through the first substrate 105 of the first semiconductor structure 102 and/or the second substrate 116 of the second semiconductor structure 104. Such substrate-level interconnection paths may be used to route electrical signals between bonding pad pairs or to form a continuous conductive chain for testing or alignment verification purposes.

FIG. 14 illustrates another simplified schematic sectional view of another chain 111a or 111b in a semiconductor device 100 or 101. In this embodiment, adjacent first bonding pad pairs 114 are interconnected through the first and second interconnect layers 108 and 120 within the first or second semiconductor structures 102 and 104. This configuration enables electrical signals to be routed through predefined metal paths formed in the interconnect stacks, supporting more flexible signal chaining and compatibility with complex multilayer metallization architectures.

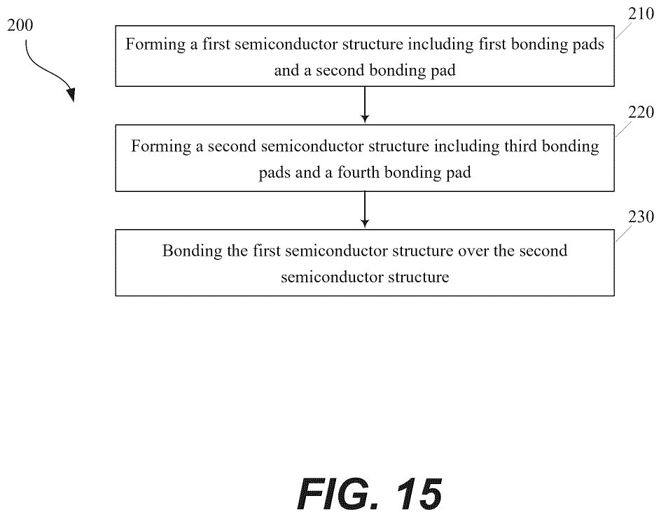

Referring to FIG. 15, in accordance with some embodiments of the present disclosure, a method 200 for manufacturing a semiconductor device 100 or 101 is provided. The method 200 includes an operation 210 of forming a first semiconductor structure 102 comprising a plurality of first bonding pads 124 and at least one second bonding pad 126. The method further includes an operation 220 forming a second semiconductor structure 104 comprising a plurality of third bonding pads corresponding to the first bonding pads 124, and a fourth bonding pad corresponding to the second bonding pad 126. The method also comprises an operation 230 of bonding the first semiconductor structure 102 over the second semiconductor structure 104, such as through a hybrid bonding process, wherein exposed metallization surfaces of the respective bonding pads are aligned and joined to form electrically conductive vias across the bonding interface 106. In some embodiments, the first bonding pads 124 and the second bonding pads 126 are aligned and bonded together to form first bonding pad pairs 114. The first bonding pad pairs 114 are then connected to each other through an internal conductive path within either the first semiconductor structure 102 or the second semiconductor structure 104, thereby forming a first chain 111a. This chain can serve as a test path or signal transmission route for evaluating bonding alignment or electrical continuity.

In some embodiments, a third bonding pad in the first semiconductor structure 102 and a fourth bonding pad in the second semiconductor structure 104 may be aligned and bonded together to form a second bonding pad pair. The second bonding pad pair may not belong to the first chain 111a, but may be positioned adjacent to at least one first bonding pad pair in the first chain 111a. In some embodiments, the second bonding pad pair belongs to the second chain 111b. In some embodiments, a first misalignment distance D1 that can be defined between a first bonding pad 124 and its corresponding second bonding pad 126, is larger than a second misalignment distance D2 that can be defined between the third bonding pad and the fourth bonding pad.

While several examples have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the examples described herein. More generally, those skilled in the art will readily appreciate that all parameters, dimensions, materials, and configurations described herein are meant to be example and that the actual parameters, dimensions, materials, and/or configurations will depend upon the specific application or applications for which the teachings is/are used. Those skilled in the art will recognize, or be able to ascertain using no more than routine experimentation, many equivalents to the specific examples described herein. It is, therefore, to be understood that the foregoing examples are presented by way of example only and that, within the scope of the appended claims and equivalents thereto, examples may be practiced otherwise than as specifically described and claimed. Examples of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

1. A semiconductor device, comprising:
a first semiconductor structure;
a second semiconductor structure bonded over the first semiconductor structure;
a first chain including a plurality of first bonding pad pairs, each first bonding pad pair including a first bonding pad in the first semiconductor structure and a second bonding pad in the second semiconductor structure that are bonded together; and
a second bonding pad pair that does not belong to the first chain and is adjacent to at least one of the first bonding pad pairs in the first chain, the second bonding pad pair including a third bonding pad in the first semiconductor structure and a fourth bonding pad in the second semiconductor structure,
wherein a first misalignment distance between the first bonding pad and the second bonding pad is larger than a second misalignment distance between the third bonding pad and the fourth bonding pad.

2. The semiconductor device of claim 1, further comprising a third bonding pad pair that does not belong to the first chain and is adjacent to the second bonding pad pair, the third bonding pad pair including a fifth bonding pad in the first semiconductor structure and a sixth bonding pad in the second semiconductor structure, wherein a first difference is a difference between the first misalignment distance and the second misalignment distance, a second difference is a difference between a third misalignment distance and the second misalignment distance, the third misalignment distance is a distance between the fifth bonding pad and the sixth bonding pad, and the first difference is greater than the second difference.

3. The semiconductor device of claim 1, wherein each bonding pad in the first and second bonding pad pairs has a substantially equal diameter, and a difference between the first and second misalignment distances is greater than one tenth of the diameter.

4. The semiconductor device of claim 3, wherein the first misalignment distance is greater than or equal to sixty percent of the diameter, and the second misalignment distance is less than sixty percent of the diameter.

5. The semiconductor device of claim 1, wherein the first and second semiconductor structures each further comprises a dielectric bonding region, where a dielectric material in the dielectric bonding regions includes carbon-doped silicon nitride.

6. The semiconductor device of claim 1, wherein the first bonding pad pair is located between a seal ring and the second bonding pad pair.

7. The semiconductor device of claim 1, wherein the adjacent first bonding pad pairs in the first chain being connected via a conductive path within either of the first or the second semiconductor structure such that the first bonding pad pairs in the first chain are connected in series.

8. The semiconductor device of claim 1, wherein the adjacent first bonding pad pairs in the first chain are connected through a first interconnect layer in the first semiconductor structure that connects the first bonding pads and a second interconnect layer in the second semiconductor structure that connects the second bonding pads.

9. The semiconductor device of claim 1, wherein the first semiconductor structure includes a first semiconductor component, and the second semiconductor structure includes a second semiconductor component, and the first semiconductor component is connected to the second semiconductor component via the second bonding pad pair.

10. The semiconductor device of claim 1, further comprising a second chain including a plurality of first bonding pad pairs, each of the first and second chains including first bonding pad pairs having misalignments in a same direction, the first bonding pad pairs within each chain being connected in series, and the first and second chains being isolated from each other.

11. The semiconductor device of claim 1, wherein the first misalignment distance is along a plane where the first bonding pad and the second bonding pad are bonded together.

12. The semiconductor device of claim 1, wherein the first and second semiconductor structures are of the same type.

13. A semiconductor device, comprising:
a first semiconductor structure;
a second semiconductor structure bonded over the first semiconductor structure;
a chain including a plurality of first bonding pad pairs, each first bonding pad pair including a first bonding pad in the first semiconductor structure and a second bonding pad in the second semiconductor structure that are bonded together; and
a second bonding pad pair that does not belong to the chain and is adjacent to the first bonding pad pair in the chain, the second bonding pad pair including a third bonding pad in the first semiconductor structure and a fourth bonding pad in the second semiconductor structure,
wherein the first bonding pad pair has a first misalignment vector indicating a first misalignment between the first bonding pad and the second bonding pad, the second bonding pad pair has a second misalignment vector indicating a second misalignment between the third bonding pad and the fourth bonding pad, and a vector difference between the first and second misalignment vectors is non-zero.

14. The semiconductor device of claim 13, wherein the first semiconductor structure includes a fifth bonding pad and the second semiconductor structure includes a sixth bonding pad, the fifth bonding pad and the sixth bonding pad are bonded together to form a third bonding pad pair that does not belong to the chain and is adjacent to the second bonding pad pair, the third bonding pad pair having a third misalignment vector, wherein a vector difference between the first and second misalignment vectors is greater than a vector difference between the third and second misalignment vectors in terms of vector length.

15. The semiconductor device of claim 13, wherein the first and second semiconductor structures each further comprises a dielectric bonding region, where a dielectric material in the dielectric bonding regions includes carbon-doped silicon nitride.

16. The semiconductor device of claim 13, wherein the first bonding pad pair is located between a seal ring and the second bonding pad pair.

17. The semiconductor device of claim 13, wherein each bonding pad in the first and second bonding pad pairs has a substantially equal diameter, and a vector difference between the first and second misalignment vectors is greater than one tenth of the diameter.

18. The semiconductor device of claim 17, wherein a length of the first misalignment vector is greater than or equal to sixty percent of the diameter, and a length of the second misalignment vector is less than sixty percent of the diameter.

19. The semiconductor device of claim 13, wherein the first semiconductor structure comprises a memory cell array and the second semiconductor structure comprises a periphery circuit of the memory cell array.

20. A method for manufacturing a semiconductor device, comprising:
forming a first semiconductor structure including first bonding pads and a second bonding pad;
forming a second semiconductor structure including third bonding pads and a fourth bonding pad; and
bonding the first semiconductor structure over the second semiconductor structure,
wherein the first bonding pads and the third bonding pads are bonded together, respectively, to form first bonding pad pairs that are connected to form a chain, at least two of the first bonding pad pairs in the chain being connected via a conductive path within either of the first or the second semiconductor structure,
wherein the second bonding pad and the fourth bonding pad are bonded together to form a second bonding pad pair that does not belong to the chain, and
wherein a first misalignment distance between the first bonding pad and the third bonding pad is larger than a second misalignment distance between the second bonding pad and the fourth bonding pad.

21-25. (canceled)
